(19) United States
(12) Patent Application Publication
(10) Pub. No.: US 2026/0372173 A1
(43) Pub. Date: Nov. 19, 2026

(54) PACKAGE STRUCTURE WITH CAPACITOR

(71) Applicant: Taiwan Semiconductor Manufacturing Company, Ltd., Hsinchu (TW)

(72) Inventor: Wen-Shiang LIAO, Miaoli County (TW)

(73) Assignee: Taiwan Semiconductor Manufacturing Company, Ltd., Hsinchu (TW)

(21) Appl. No.: 19/751,223

(22) Filed: Jul. 23, 2026

Related U.S. Application Data
(62) Division of application No. 18/297,872, filed on Apr. 10, 2023.

(51) Int. Cl. H10W 74/10; H10D 1/60; H10D 1/68; H10D 80/20; H10P 14/40; H10P 14/47; H10P 14/60; H10P 14/68; H10P 50/00; H10P 52/00; H10P 52/40; H10P 72/70; H10P 95/00; H10W 70/05; H10W 70/09; H10W 70/60; H10W 70/652; H10W 72/00; H10W 72/30; H10W 74/01; H10W 74/47

(52) U.S. Cl. CPC H10W 74/117; H10D 1/60; H10D 1/68; H10D 80/215; H10P 14/40; H10P 14/60; H10W 70/09; H10W 72/823; H10W 74/01; H10W 74/114; H10W 74/124; H10P 14/47; H10P 14/6342; H10P 14/68; H10P 50/73; H10P 52/00; H10P 52/40; H10P 52/409; H10P 72/74; H10P 72/7412; H10P 72/7424; H10P 72/743; H10P 95/08; H10W 70/05; H10W 70/60; H10W 70/6528; H10W 72/30; H10W 74/47; H10W 74/473

(57) ABSTRACT

A package structure is provided. The package structure includes a semiconductor chip and a first dielectric structure laterally spaced apart from the semiconductor chip. The first dielectric structure has a first dielectric constant. The package structure also includes a second dielectric structure laterally spaced apart from the semiconductor chip and a protective layer laterally surrounding the semiconductor chip, the first dielectric structure. The second dielectric structure, wherein the protective layer has a second dielectric constant, and the second dielectric constant is lower than the first dielectric constant. The package structure further includes a redistribution structure over the semiconductor chip, the first dielectric structure, the second dielectric structure, and the protective layer.

### PRIORITY CLAIM AND CROSS-REFERENCE

This Application is a Divisional of U.S. application Ser. No. 18/297,872, filed on Apr. 10, 2023, the entirety of which is incorporated by reference herein.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A package structure not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor chips. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1V are cross-sectional views of various stages of a process for forming a portion of a package structure, in accordance with some embodiments.

FIGS. 2A-2L are plan views each showing a portion of a capacitor element of a package structure, in accordance with some embodiments.

FIG. 3 is a cross-sectional view of a portion of a package structure, in accordance with some embodiments.

FIGS. 4A-4G are cross-sectional views of various stages of a process for forming a portion of a package structure, in accordance with some embodiments.

FIGS. 5A-5G are cross-sectional views of various stages of a process for forming a portion of a package structure, in accordance with some embodiments.

FIGS. 6A-6F are cross-sectional views of various stages of a process for forming a portion of a package structure, in accordance with some embodiments.

FIG. 7 is a plan view of a portion of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher of what is specified, such as 95% or higher, especially 99% or higher, including 100%. Furthermore, terms such as “substantially parallel” or “substantially perpendicular” are to be interpreted as not to exclude insignificant deviation from the specified arrangement and may include for example deviations of up to 10 degrees. The word “substantially” does not exclude “completely” e.g. a composition which is “substantially free” from Y may be completely free from Y.

Terms such as “about” in conjunction with a specific distance or size are to be interpreted so as not to exclude insignificant deviation from the specified distance or size and may include for example deviations of up to 10%. The term “about” in relation to a numerical value x may mean x ±5 or 10%.

Some embodiments of the disclosure are described. Additional operations can be provided before, during, and/or after the stages described in these embodiments. Some of the stages that are described can be replaced or eliminated for different embodiments. Additional features can be added to the semiconductor device structure and/or the package structure. Some of the features described below can be replaced or eliminated for different embodiments. Although some embodiments are discussed with operations performed in a particular order, these operations may be performed in another logical order.

Embodiments of the disclosure may relate to package structures such as three-dimensional (3D) packaging, 3D-IC devices, and 2.5D packaging. Embodiments of the disclosure form a package structure including a substrate that carries one or more dies or packages and a protective element (such as a protective lid) aside the dies or packages. The protective element may also function as a warpage-control element and/or heat dissipation element.

Other features and processes may also be included. For example, testing structures may be included to aid in the verification testing of the 3D packaging, 3DIC devices, and/or 2.5 D packaging. The testing structures may include, for example, test pads formed in a redistribution layer or on a substrate that allows testing to be conducted using probes or probe cards and the like. Verification testing may be performed on intermediate structures as well as the final structure. Additionally, the structures and methods disclosed herein may be used in conjunction with testing methodologies that incorporate intermediate verification of known good dies to increase the yield and decrease costs.

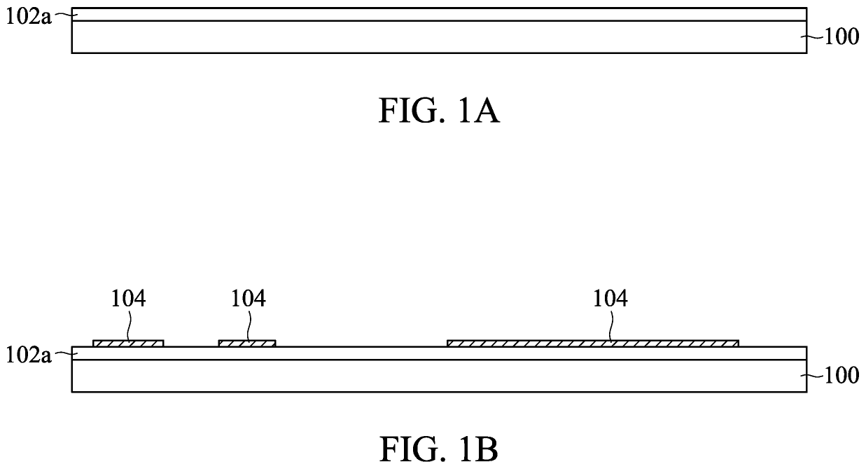

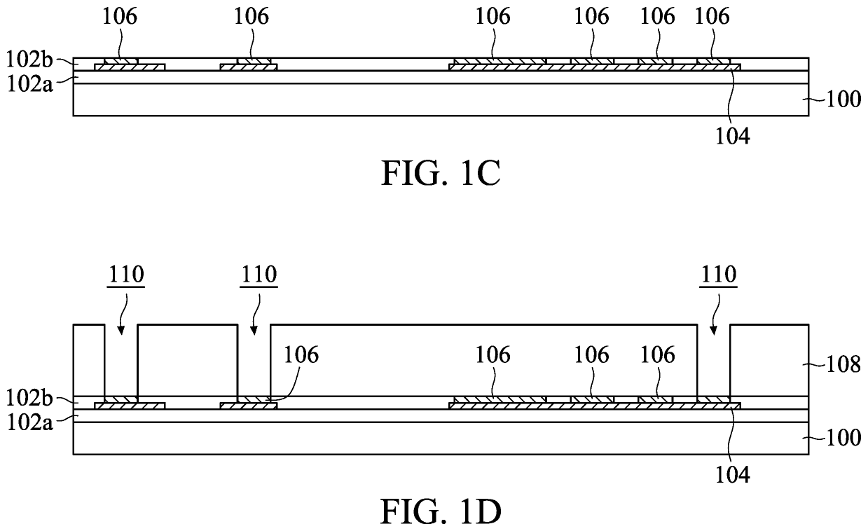

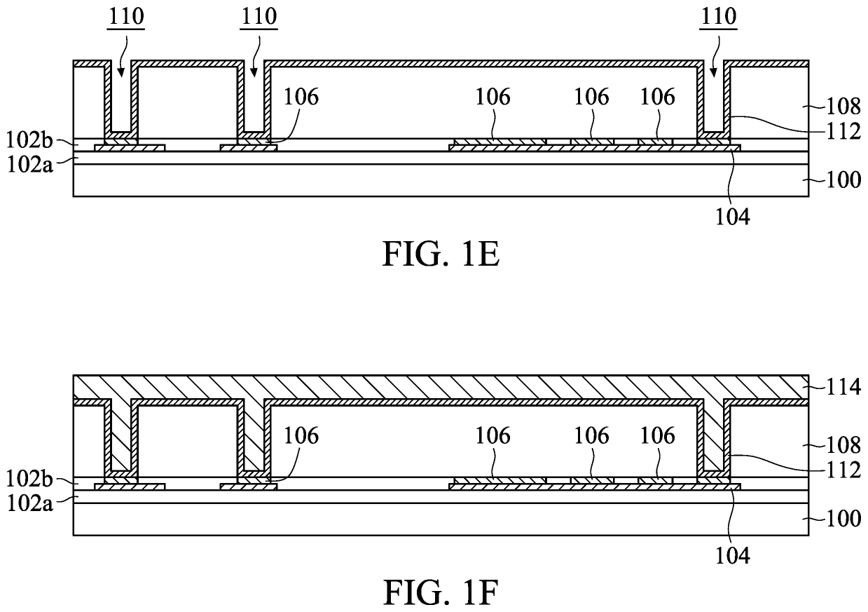

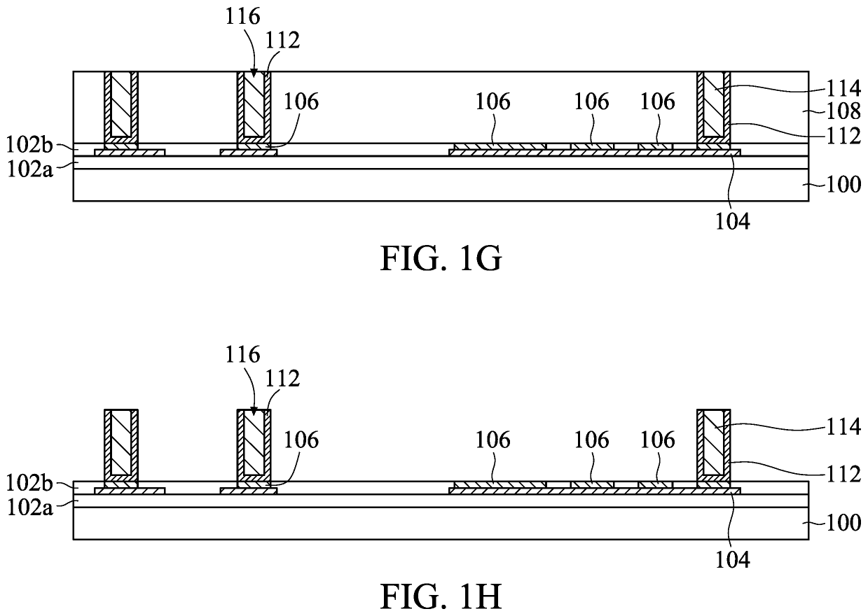

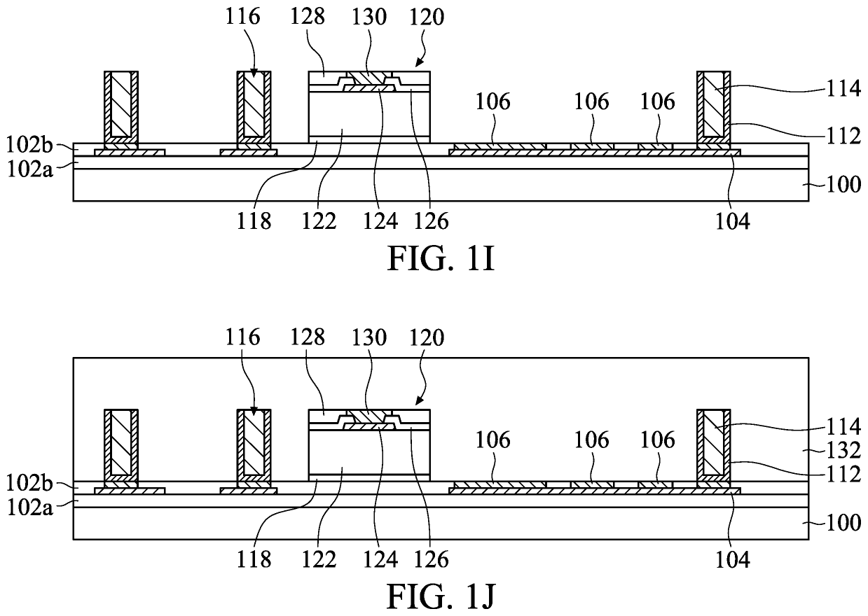

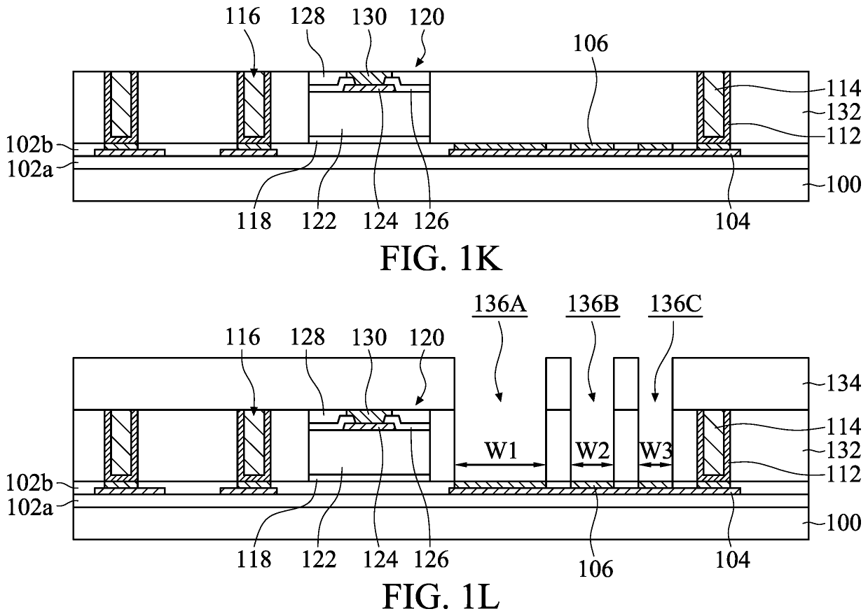

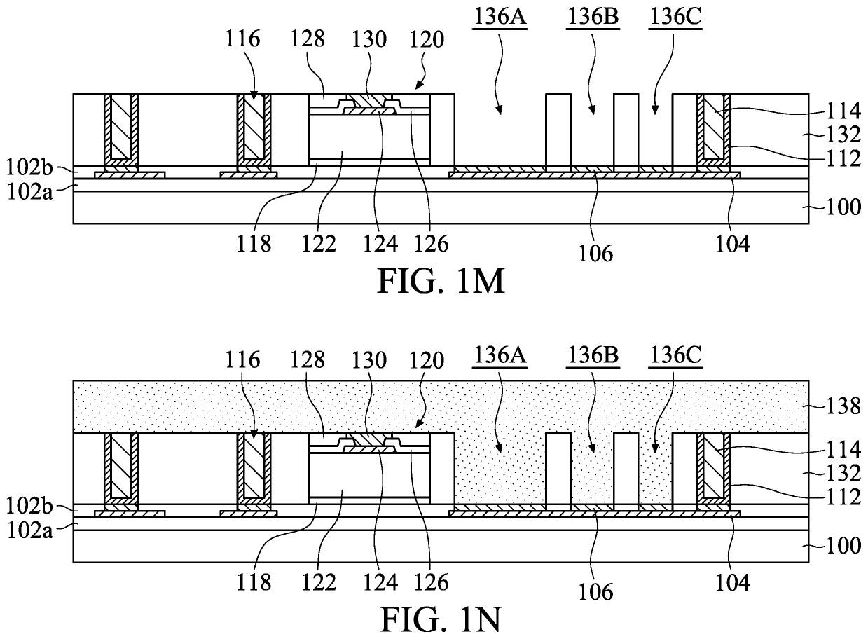

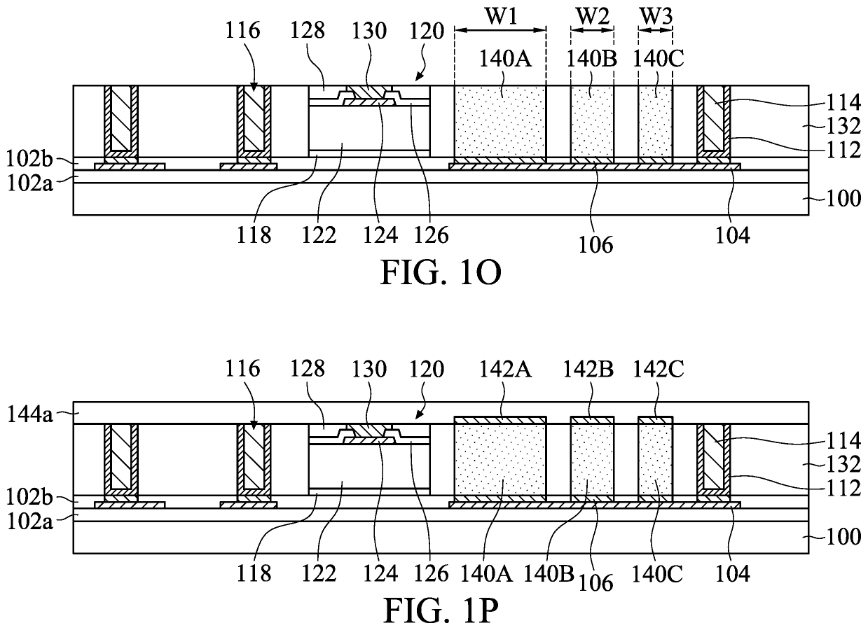

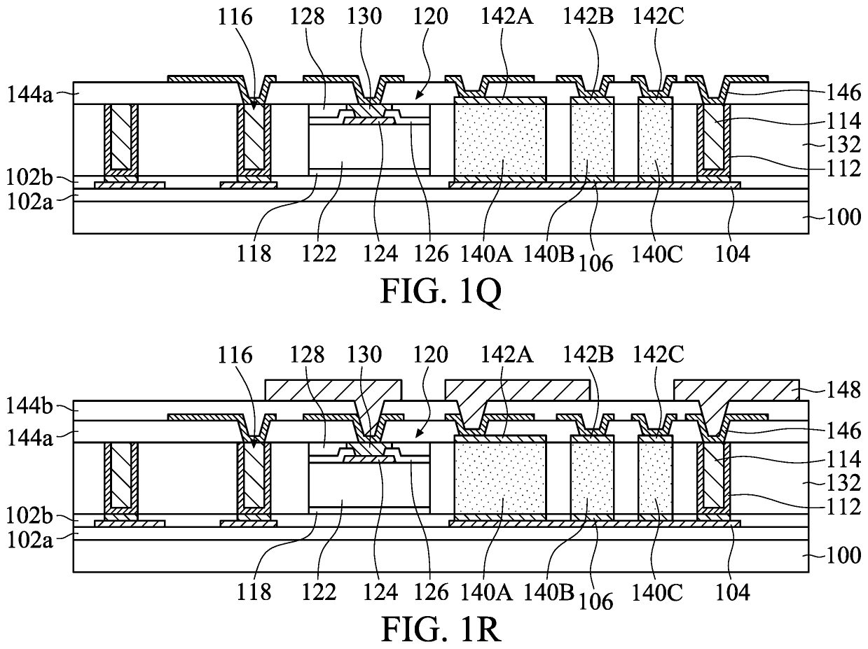

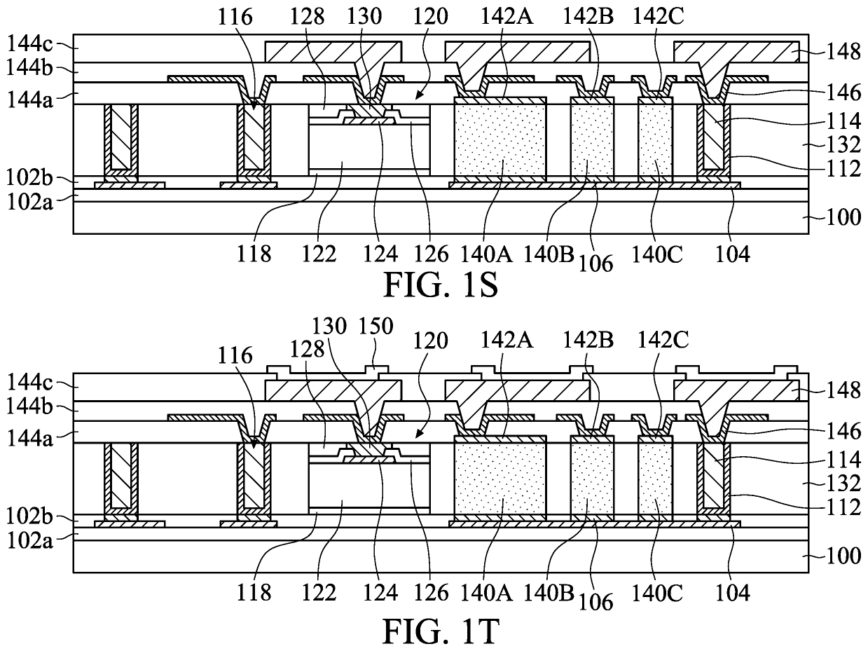

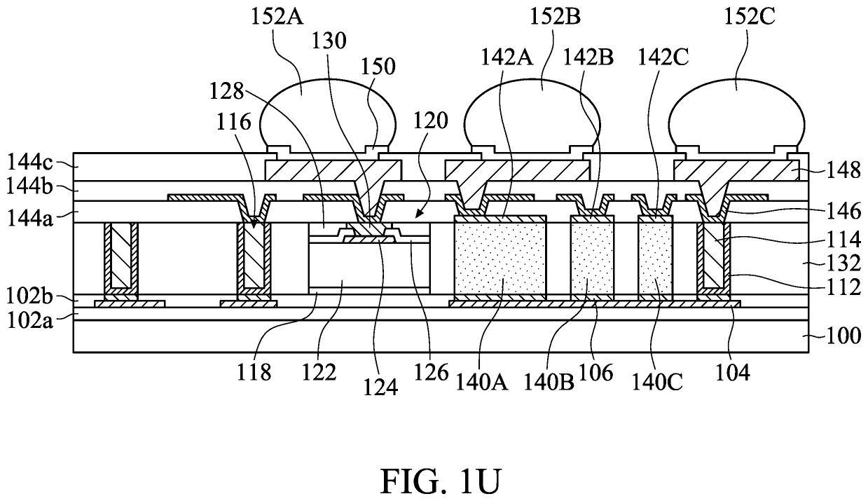

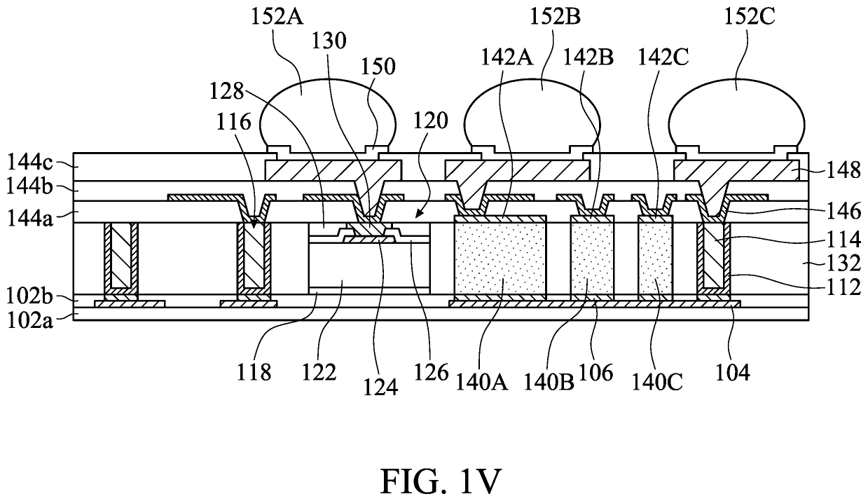

FIGS. 1A-1V are cross-sectional views of various stages of a process for forming a portion of a package structure, in accordance with some embodiments. As shown in FIG. 1A, a carrier substrate 100 is provided or received. The carrier substrate 100 may include a glass substrate (such as a glass wafer), a semiconductor substrate (such as a silicon wafer), a metal substrate, an insulating substrate, one or more another suitable substrate, or a combination thereof.

Afterwards, an insulating layer 102a is formed over the carrier substrate 100, as shown in FIG. 1A in accordance with some embodiments. The insulating layer 102a may be made of or include a polymer material. The polymer material may be made of or include polybenzoxazole (PBO), polyimide, epoxy-based resin, another suitable polymer material, or a combination thereof. In some other embodiments, the insulating layer 102a is made of or includes silicon nitride, silicon oxide, silicon oxynitride, silicon carbide, another suitable dielectric material, or a combination thereof. In some embodiments, the insulating layer 102a is formed using a spin-on process, a spray coating process, a chemical vapor deposition (CVD) process, another applicable process, or a combination thereof.

In some embodiments, before the formation of the insulating layer 102a, an adhesive film is formed or disposed over the carrier substrate 100. The adhesive film may be a detachable film such as a light transfer heat conversion (LTHC) film. The adhesive film and the carrier substrate 100 may thus be detachable in a subsequent process.

As shown in FIG. 1B, multiple conductive features 104 are formed over the insulating layer 102a, in accordance with some embodiments. The conductive features 104 may be made of or include copper, titanium, aluminum, gold, platinum, cobalt, tungsten, another suitable material, or a combination thereof. Each of the conductive features 104 may have a thickness that is within a range from about 7 μm to about 9 μm. In some embodiments, the rightmost conductive feature 104 in FIG. 1B functions as a grounding layer. In some embodiments, multiple grounding layers are formed.

In some embodiments, a seed layer is deposited over the insulating layer 102a. The seed layer may include multiple sub-layers. The sub-layers may include a titanium layer and a copper layer. The titanium layer may have a thickness that is within a range from about 50 nm to about 150 nm. The copper layer may have a thickness that is within a range from about 450 nm to about 550 nm. Afterwards, a conductive layer is electroplated on the seed layer. Then, a photolithography process and an etching process are used to partially remove the conductive layer and the seed layer. As a result, the remaining portions of the seed layer and the conductive layer form the conductive features 104.

As shown in FIG. 1C, an insulating layer 102b is formed over the insulating layer 102a and the conductive features 104, in accordance with some embodiments. The material and formation method of the insulating layer 102b may be the same as or similar to those of the insulating layer 102a.

Afterwards, the insulating layer 102b is patterned to form multiple openings that partially expose the conductive features. In some embodiments, the insulating layer 102b is made of a photosensitive material. A photolithography process may be used to form the openings.

Afterwards, conductive features 106 are formed in the openings, as shown in FIG. 1C in accordance with some embodiments. The conductive features 106 may function as conductive vias for forming electrical connection between the underlying elements and the overlying elements that will be formed later. The insulating layers 102a and 102b and the conductive features 104 and 106 may together function as a redistribution structure that is used for routing.

The conductive features 106 may be made of or include copper, titanium, aluminum, gold, platinum, cobalt, tungsten, another suitable material, or a combination thereof. The conductive features 106 may be formed using an electroplating process, an electrochemical plating process, a CVD process, a physical vapor deposition (PVD) process, another applicable process, or a combination thereof.

As shown in FIG. 1D, a patterned mask element 108 is formed over the insulating layer 102b and the conductive features 106, in accordance with some embodiments. The patterned mask element 108 has multiple openings 110 that expose some of the conductive features 106. In some embodiments, the patterned mask element 108 is a patterned photoresist layer. In some other embodiments, the patterned mask element 108 is a photosensitive dry film. The photosensitive dry film may be laminated onto the insulating layer 102b and the conductive features 106. Afterwards, the photosensitive dry film is partially irradiated and partially removed. As a result, the photosensitive dry film is patterned, and the openings 110 are formed. The openings 110 may be used to contain conductive structures (such as through insulator vias) that will be formed later.

As shown in FIG. 1E, a seed layer 112 is deposited over the patterned mask element 108, in accordance with some embodiments. The seed layer 112 extends along the sidewalls and bottoms of the openings 110. In some embodiments, the seed layer 112 is in direct contact with some of the conductive features 106. The seed layer 112 may be made of or include copper, titanium, another suitable material, or a combination thereof. The seed layer 112 may be deposited using a PVD process, a CVD process, another applicable process, or a combination thereof.

Many variations and/or modifications can be made to embodiments of the disclosure. In some other embodiments, the seed layer 112 is not formed.

As shown in FIG. 1F, a conductive layer 114 is formed on the seed layer 112, in accordance with some embodiments. In some embodiments, the conductive layer 114 overfills the openings 110. The conductive layer 114 may be made of or include copper, titanium, aluminum, gold, platinum, cobalt, tungsten, another suitable material, or a combination thereof. The conductive layer 114 may be formed using an electroplating process, an electrochemical plating process, another applicable process, or a combination thereof.

As shown in FIG. 1G, the seed layer 112 and the conductive layer 114 are partially removed, in accordance with some embodiments. As a result, the remaining portions of the seed layer 112 and the conductive layer 114 together form multiple conductive structures 116. The conductive structures 116 may function as through insulator vias (TIVs).

In some embodiments, a planarization process is used to partially remove the seed layer 112 and the conductive layer 114. Therefore, the portions of the seed layer 112 and the conductive layer 114 that are outside of the openings 110 are removed. The planarization process may include a chemical mechanical polishing (CMP) process, a grinding process, an etching process, another applicable process, or a combination thereof.

As shown in FIG. 1H, after the formation of the conductive structures 116, the patterned mask element 108 is removed, in accordance with some embodiments. The sidewalls of the conductive structures 116 are thus exposed. Some of the conductive features 106 are also exposed, as shown in FIG. 1H.

As shown in FIG. 1I, a semiconductor chip 120 is disposed over the insulating layer 102b. The semiconductor chip 120 may be a single semiconductor chip, system-on-integrated-chips (SoIC), and/or a package including one or more semiconductor chips that are encapsulated or protected. For the system-on-integrated-chips, multiple semiconductor chiplets may be stacked and bonded together to form electrical connections between these semiconductor chiplets. These semiconductor chiplets may be bonded to each other through hybrid bonding that may include dielectric-to-dielectric bonding and metal-to-metal bonding. In some embodiments, multiple semiconductor chips are disposed over the insulating layer 102b. For simplicity, only one semiconductor chip 120 is shown in FIG. 1I.

In some embodiments, the semiconductor chip 120 includes a semiconductor substrate 122, a top metal layer 124, an insulating layer 126, a passivation layer 128, and a conductive pad 130 of the semiconductor chip 120. In some embodiments, the semiconductor chip 120 is attached to the insulating layer 102b using an adhesive layer 118. The adhesive layer 118 may be a die attach film (DAF). The adhesive layer 118 may have a thickness that is within a range from about 5 μm to about 15 μm.

As shown in FIG. 1J, a protective layer 132 is formed over the semiconductor chip 120, the conductive structures 116, and the insulating layer 102b, in accordance with some embodiments. In some embodiments, the protective layer 132 is made of or includes an insulating material such as a molding material. The molding material may include a polymer material, such as an epoxy-based resin with fillers dispersed therein. The fillers may include fibers (such as silica fibers and/or carbon-containing fibers), particles (such as silica particles and/or carbon-containing particles), or a combination thereof. In some embodiments, the dielectric constant of the protective layer 132 is about 2.8.

In some embodiments, a molding material (such as a flowable molding material) is introduced or injected to cover the semiconductor chip 120, the conductive structures 116, and the insulating layer 102b. In some embodiments, a thermal process is then used to cure the flowable molding material and to transform it into the protective layer 132.

As shown in FIG. 1K, a planarization process is performed to the protective layer 132 to improve the flatness of the protective layer 132, in accordance with some embodiments. For example, the planarization process may include a grinding process, a CMP process, a dry polishing process, another applicable process, or a combination thereof. In some embodiments, after the planarization process, the surfaces of the semiconductor chip 120 and the conductive structures 116 are exposed. As shown in FIG. 1K, the conductive pad 130 of the semiconductor chip 120 is exposed. In some embodiments, the top surface of the protective layer 132 is substantially level with the surfaces of the semiconductor chip 120 and the conductive structures 116.

As shown in FIG. 1L, a patterned mask element 134 is formed over the protective layer 132, the semiconductor chip 120, and the conductive structures 116, in accordance with some embodiments. The patterned mask element 134 may be a patterned photoresist layer. The patterned mask element 134 has multiple openings that define the positions and profiles of multiple dielectric structures that will be formed later. These dielectric structures may function as capacitor dielectric structures of multiple capacitors. By fine-tuning the size, profile, and/or shape of the openings, the capacitance of the capacitors may be tuned accordingly.

Afterwards, with the patterned mask element 134 as an etching mask, the protective layer 132 is partially removed using one or more etching processes, as shown in FIG. 1L in accordance with some embodiments. As a result, openings 136A, 136B, and 136C are formed. As shown in FIG. 1L, the openings 136A, 136B, and 136C have widths W1, W2, and W3, respectively. In some embodiments, the opening 136A is wider than the opening 136B, and the opening 136B is wider than the opening 136C.

Many variations and/or modifications can be made to embodiments of the disclosure. In some other embodiments, the openings 136A-136C are formed using an energy beam drilling process. The energy beam used in the energy beam drilling process may include a laser beam, an electron beam, an ion beam, or a combination thereof. In some embodiments, the patterned mask element 134 is not formed.

As shown in FIG. 1M, the patterned mask element 134 is stripped, in accordance with some embodiments. As shown in FIG. 1M, the openings 136A-136C expose the conductive features 106 that are electrically connected to the conductive feature 104 that may function as a grounding layer. In some embodiments, the rightmost conductive structure 116 in FIG. 1M is also electrically connected to the conductive feature 104 that may function as a grounding layer.

As shown in FIG. 1N, an insulating layer 138 is formed to overfill the openings 136A-136C, in accordance with some embodiments. In some embodiments, the dielectric constant of the insulating layer 138 is higher than that of the protective layer 132. The insulating layer 138 may be made of or include a polymer material, an oxide material, a nitride material, another suitable material, or a combination thereof.

In some embodiments, the insulating layer 138 is formed from a liquid-phase polymer material with a high dielectric constant. For example, a liquid-phase polymer material that includes polybenzoxazole (PBO) and/or polyimide may be applied, spun-on, or dispensed to overfill the openings 136A-136C. Afterwards, a low-temperature curing operation is used to harden the liquid-phase polymer material. As a result, the insulating layer 138 is formed. The curing temperature of the low-temperature curing operation may be within a range from about 50 degrees C to about 300 degrees C.

In some embodiments, the insulating layer 138 includes a polymer material with fillers dispersed therein. The polymer material may include an epoxy-based resin. The fillers have high dielectric constant. The fillers may include oxide materials. The fillers may be made of or include zirconium oxide, aluminum oxide, hafnium oxide, zirconium titanium oxide, titanium oxide, tantalum oxide, another suitable material, or a combination thereof. The fillers may include fibers, particles, or a combination thereof. In some embodiments, the fillers are introduced into a liquid-phase polymer material. Afterwards, the liquid-phase polymer material and the fillers are applied, dispensed, or spun-on to overfill the openings 136A-136C. Afterwards, a low-temperature curing operation is used to harden the liquid-phase polymer material. As a result, the insulating layer 138 is formed. The curing temperature of the low-temperature curing operation may be within a range from about 50 degrees C to about 300 degrees C.

In some embodiments, the insulating layer 138 is made of or includes a high-k material such as titanium oxide, strontium titanium oxide (STO), barium titanium oxide (BTO), barium strontium titanium oxide (BST), lead zirconium titanium oxide (PZT), silicon nitride, silicon oxide, silicon oxynitride, another suitable material, or a combination thereof. The insulating layer 138 may be formed using a vapor deposition process. The vapor deposition process may include an atmospheric pressure chemical vapor deposition (APCVD) process, a sub-atmospheric chemical vapor deposition (SACVD) process, a microwave CVD process, a plasma-enhanced chemical vapor deposition (PECVD) process, a metal-organic chemical vapor deposition (MOCVD) process, an atomic layer deposition (ALD) process, another applicable process, or a combination thereof. The deposition temperature may be within a range from about 150 degrees C to about 250 degrees C.

In some other embodiments, a liquid-phase slurry paste containing particles of the high-k material is applied, spun-on, or dispensed to overfill the openings 136A-136C. Afterwards, a low-temperature curing operation is used to harden and to remove solvent of the liquid-phase paste. As a result, the insulating layer 138 is formed. The curing temperature of the low-temperature curing operation may be within a range from about 50 degrees C to about 300 degrees C.

Afterwards, the insulating layer 138 is planarized, as shown in FIG. 1O in accordance with some embodiments. As a result, the remaining portions of the insulating layer 138 form multiple dielectric structures 140A, 140B, and 140C in the openings. In some embodiments, the dielectric structure 140A is wider and larger than the dielectric structure 140B, and the dielectric structure 140B is wider and larger than the dielectric structure 140C. In some embodiments, each of the dielectric structures 140A, 140B, and 140C is substantially as thick as the protective layer 132, as shown in FIG. 1O.

In some embodiments, the dielectric structures 140A, 140B, and 140C function as capacitor dielectric structures of decoupling capacitors. In some embodiments, the dielectric structure 140A provides higher capacitance than the dielectric structure 140B, and the dielectric structure 140B provides higher capacitance than the dielectric structure 140C.

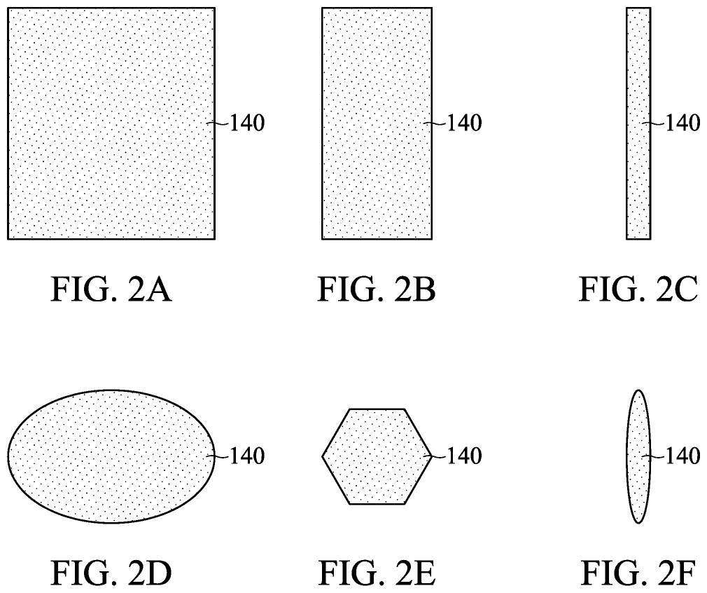

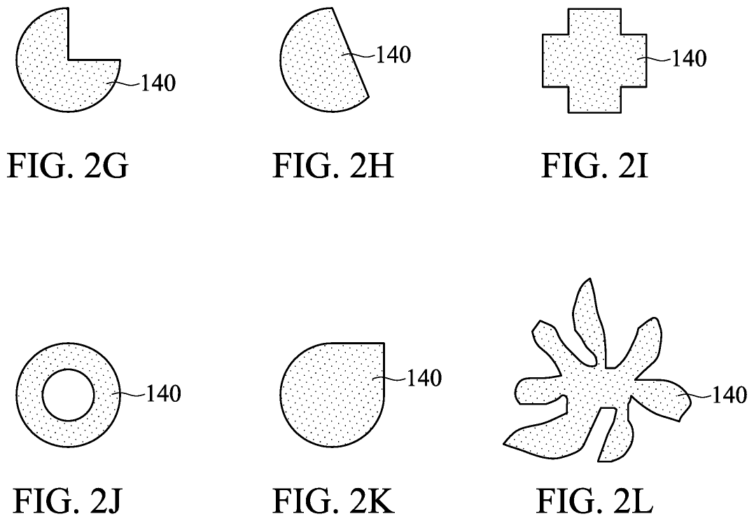

FIGS. 2A-2L are plan views each showing a portion of a capacitor element of a package structure, in accordance with some embodiments. FIGS. 2A-2L show the plan views of multiple dielectric structures 140. Each of the dielectric structures 140A-140C may be formed to have one of the plan views shown in FIGS. 2A-2L. By fine-tuning the size, profile, and/or shape of the dielectric structures, the capacitance of the capacitors may be tuned accordingly.

As shown in FIG. 1P, conductive features 142A, 142B, and 142C are respectively formed over the dielectric structures 140A, 140B, and 140C, in accordance with some embodiments. The conductive features 142A, the dielectric structure 140A, and the conductive feature 106 below the dielectric structure 140A may together form a first capacitor element. The material and formation method of the conductive features 142A-142C may be the same as or similar to those of the conductive features 104 and 106.

The conductive features 142A may function as a top electrode of the first capacitor element, and the conductive feature 106 below the dielectric structure 140A may function as a bottom electrode of the first capacitor element. The conductive features 142B, the dielectric structure 140B, and the conductive feature 106 below the dielectric structure 140B may together form a second capacitor element. The conductive features 142B may function as a top electrode of the second capacitor element, and the conductive feature 106 below the dielectric structure 140B may function as a bottom electrode of the second capacitor element. The conductive features 142C, the dielectric structure 140C, and the conductive feature 106 below the dielectric structure 140C may together form a third capacitor element. The conductive features 142C may function as a top electrode of the third capacitor element, and the conductive feature 106 below the dielectric structure 140C may function as a bottom electrode of the third capacitor element.

Afterwards, an insulating layer 144a is formed over the semiconductor chip 120, the protective layer 132, the conductive structures 116, and the conductive features 142A-142C, as shown in FIG. 1P in accordance with some embodiments. The material and formation method of the insulating layer 144a may be the same as or similar to those of the insulating layers 102a and 102b.

As shown in FIG. 1Q, the insulating layer 144a is patterned to form multiple openings, in accordance with some embodiments. The openings may expose the conductive structures 116, the conductive pad 130 of the semiconductor chip 120, and the conductive features 142A-142C. One or more photolithography processes and one or more etching processes may be used to pattern the insulating layer 144a. In some embodiments, the insulating layer 144a is made of a photosensitive polymer material. The openings may be formed using a photolithography process.

Afterwards, conductive features 146 are formed over the conductive structures 116, the conductive pad 130 of the semiconductor chip 120, and the conductive features 142A-142C, as shown in FIG. 1Q in accordance with some embodiments. The conductive features 146 extend over the top surface of the insulating layer 144a and extend into the openings. The material and formation method of the conductive features 146 may be the same as or similar to those of the conductive features 104.

As shown in FIG. 1R, an insulating layer 144b and multiple conductive features 148 are formed, in accordance with some embodiments. The conductive features 148 may fill the openings formed in the insulating layer 144a. The material and formation method of the insulating layer 144b may be the same as or similar to those of the insulating layer 144a. The material and formation method of the conductive features 148 may be the same as or similar to those of the conductive features 146.

As shown in FIG. 1S, an insulating layer 144c is formed over the insulating layer 144b and the conductive features 148, in accordance with some embodiments. The material and formation method of the insulating layer 144c may be the same as or similar to those of the insulating layer 144a. The insulating layers 144a-144c and the conductive features 142A-142C, 146, and 148 may together form a redistribution structure that is used for routing.

As shown in FIG. 1T, the insulating layer 144c is partially removed, and under bump metallization (UBM) structures 150 are then formed, in accordance with some embodiments. The UBM structures 150 may be used to hold or receive conductive bumps that will be formed later. The UBM structures 150 may be a single layer or a stack of multiple sub-layers. For example, the UBM structures 150 may be made of or include Ti, TiW, TiCu, Ni, Cu, another suitable material, or a combination thereof. In some embodiments, the UBM structures 150 includes sub-layers including, for example, a glue layer (or a diffusion barrier layer) and a seed layer.

In some embodiments, the glue layer is made of or includes titanium nitride (TiN), titanium (Ti), tantalum (Ta), tantalum nitride (TaN), one or more other suitable materials, or a combination thereof. In some embodiments, the seed layer is a copper-containing seed layer formed on the glue layer. The copper-containing seed layer may be made of or include pure copper or one of many copper alloys that include silver, chromium, nickel, tin, gold, one or more other suitable elements, or a combination thereof.

In some embodiments, an UBM layer is deposited by using a physical vapor deposition (PVD) process (including, for example, a sputtering process or an evaporation process), a chemical vapor deposition (CVD) process, an atomic layer deposition (ALD) process, an electroless plating process, another applicable process, or a combination thereof. Afterwards, the UBM layer is patterned to form the UBM structures 150.

As shown in FIG. 1U, multiple conductive bumps including conductive bumps 152A, 152B, and 152C are formed over the UBM structures 150, in accordance with some embodiments. The conductive bump 152A may be electrically connected to the conductive pad 130 of the semiconductor chip 120. The conductive bump 152B may be electrically connected to the conductive feature 142A that functions as the top electrode of the first capacitor element. Other conductive bumps (not shown in FIG. 1U) may be formed to form electrical connections to the conductive features 142B and 142C. The conductive bump 152C is electrically connected to the conductive structure 116 that is further electrically connected to the conductive feature 104 that functions as a grounding layer.

The conductive bumps 152A, 152B, and 152C may be made of or include tin-containing solder materials. The tin-containing solder materials may further include copper, silver, gold, aluminum, lead, another suitable material, or a combination thereof. In some other embodiments, the conductive bumps 152A-152C are lead-free.

As shown in FIG. 1V, the carrier substrate 100 is removed, in accordance with some embodiments. A light irradiation operation may be used to remove the carrier substrate 100 and the LTHC film. In some embodiments, a sawing operation is used to form multiple package structures. One of the package structures is shown in FIG. 1V. In some embodiments, the edges of the protective layer 132 and the insulating layers 102a-102b and 144a-144c are vertically aligned with each other.

In some embodiments, the dielectric structures 140A-140C are made of the same material and thus have the same dielectric constant. The dielectric structure 140A may provide higher capacitance than the dielectric structure 140B or 140C since the dielectric structure 140A occupies larger area. However, embodiments of the disclosure are not limited thereto. Many variations and/or modifications can be made to embodiments of the disclosure. In some other embodiments, the dielectric structures are made of different materials. In some embodiments, the dielectric structures have different dielectric constants.

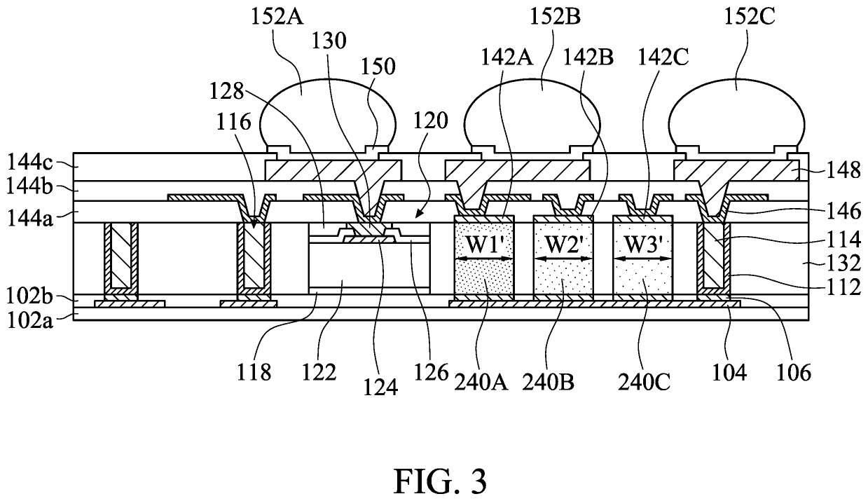

FIG. 3 is a cross-sectional view of a portion of a package structure, in accordance with some embodiments. In some embodiments, a package structure that is similar to the package structure shown in FIG. 1V is formed. In some embodiments, the package structure includes dielectric structures 240A, 240B, and 240C. In some embodiments, the dielectric structures 240A-240C are made of different materials and have different dielectric constants. In some embodiments, the dielectric structure 240A has a higher dielectric constant than that of the dielectric structure 240B, and the dielectric structure 240B has a higher dielectric constant than that of the dielectric structure 240C. As shown in FIG. 3, the dielectric structures 240A, 240B, and 240C have widths W1′, W2′, and W3′, respectively. In some embodiments, the widths W1′, W2′, and W3′ are substantially the same.

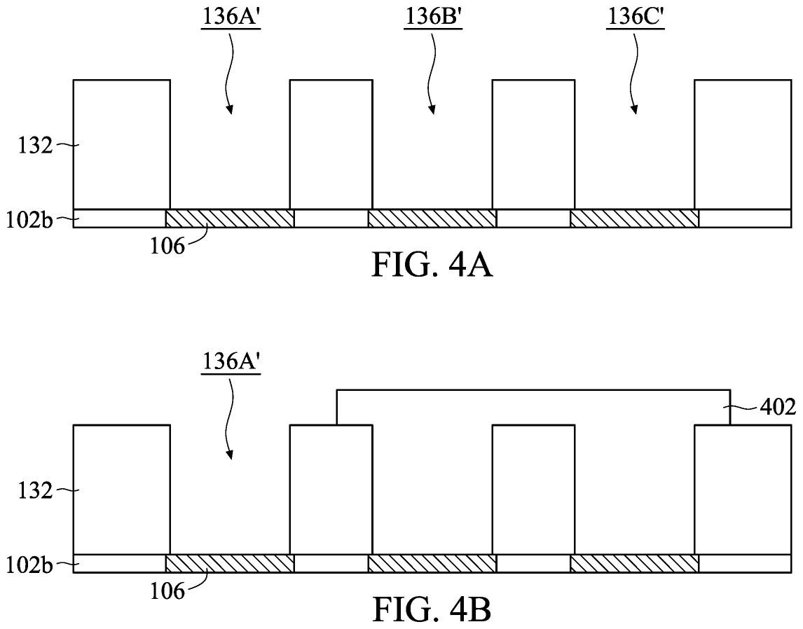

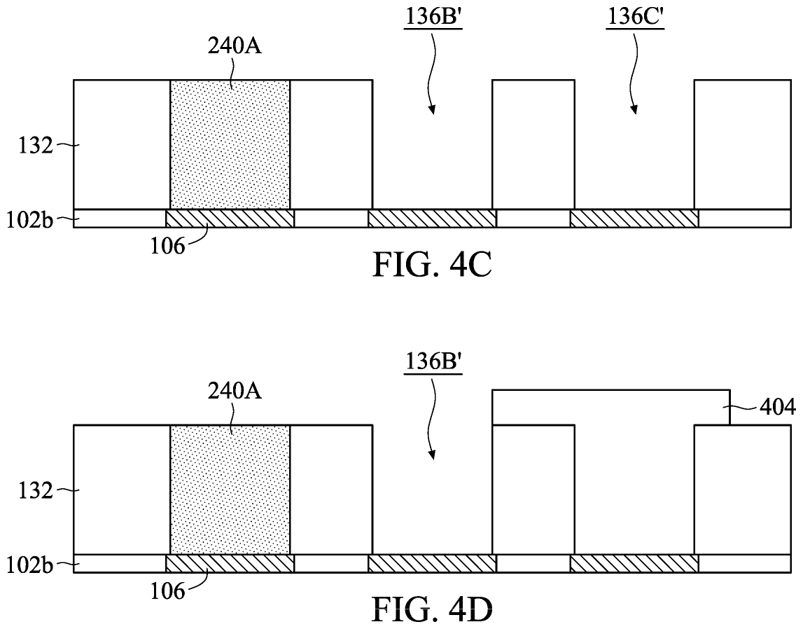

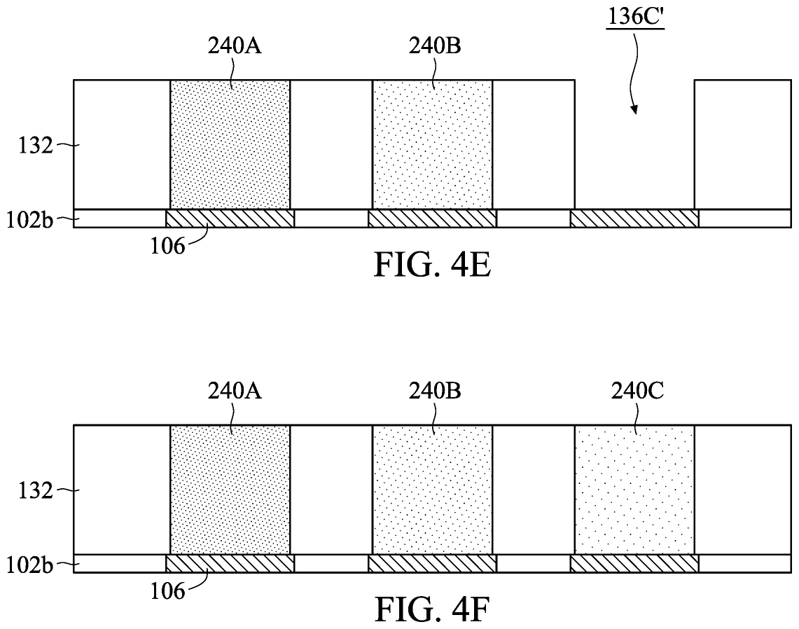

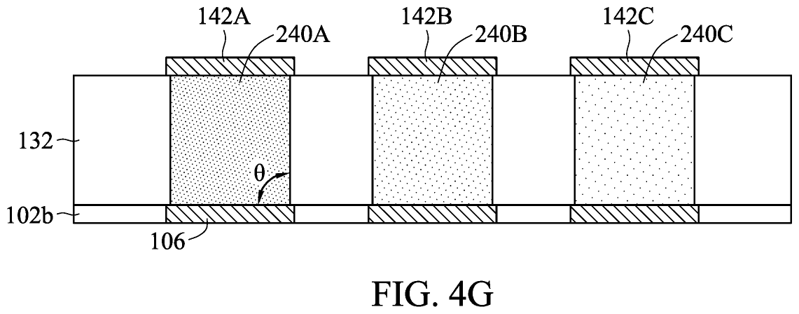

FIGS. 4A-4G are cross-sectional views of various stages of a process for forming a portion of a package structure, in accordance with some embodiments. In some embodiments, FIGS. 4A-4G show the formation of the dielectric structures 240A-240C shown in FIG. 3.

As shown in FIG. 4A, similar to the embodiments illustrated in FIGS. 1L-1M, the protective layer 132 is patterned to form openings 136A′, 136B′, and 136C′, in accordance with some embodiments. In some embodiments, the openings 136A′-136C′ have substantially the same width.

As shown in FIG. 4B, a patterned mask element 402 is formed to cover the openings 136B′ and 136C′, in accordance with some embodiments. The opening 136A′ is not covered by the patterned mask element 402. The patterned mask element 402 may be a patterned photoresist layer.

As shown in FIG. 4C, the dielectric structure 240A is formed in the opening 136A′, in accordance with some embodiments. The material and formation method of the dielectric structure 240A may be the same as or similar to those of the dielectric structure 140A. During the formation of the dielectric structure 240A, the openings 136B′ and 136C′ are filled with a remaining portion of the patterned mask element 402. As a result, the material used for forming the dielectric structure 240A is prevented from entering the openings 136B′ and 136C′. After the formation of the dielectric structure 240A, the patterned mask element 402 is removed, as shown in FIG. 4C in accordance with some embodiments.

As shown in FIG. 4D, a patterned mask element 404 is formed to cover the opening 136C′, in accordance with some embodiments. The opening 136B′ is not covered by the patterned mask element 404. The patterned mask element 404 may be a patterned photoresist layer.

As shown in FIG. 4E, the dielectric structure 240B is formed in the opening 136B′, in accordance with some embodiments. The material and formation method of the dielectric structure 240B may be the same as or similar to those of the dielectric structure 140A. In some embodiments, the dielectric structures 240B and 240A are made of different materials. In some embodiments, the dielectric structure 240B has a lower dielectric constant than that of the dielectric structure 240A.

During the formation of the dielectric structure 240B, the opening 136C′ is filled with a remaining portion of the patterned mask element 404, and the opening 136A′ is occupied by the dielectric structure 240A. As a result, the material used for forming the dielectric structure 240B is prevented from entering the openings 136A′ and 136C′. After the formation of the dielectric structure 204B, the patterned mask element 404 is removed, as shown in FIG. 4E in accordance with some embodiments.

As shown in FIG. 4F, the dielectric structure 240C is formed in the opening 136C′, in accordance with some embodiments. The material and formation method of the dielectric structure 240C may be the same as or similar to those of the dielectric structure 140A. In some embodiments, the dielectric structures 240C and 240B and/or 240A are made of different materials. In some embodiments, the dielectric structure 240B has a lower dielectric constant than that of the dielectric structure 240C.

During the formation of the dielectric structure 240C, the openings 136A′ and 136B′ are occupied by the dielectric structures 240A and 240B, respectively. As a result, the material used for forming the dielectric structure 240C is prevented from entering the openings 136A′ and 136B′.

As shown in FIG. 4G, similar to the embodiments illustrated in FIG. 1P, conductive features 142A, 142B, and 142C are respectively formed over the dielectric structures 240A, 240B, and 240C, in accordance with some embodiments. As a result, multiple capacitor elements are formed. In some embodiments, the capacitor element having the dielectric structure 240A has higher capacitance than that of the capacitor element having the dielectric structure 240B or 240C.

In some embodiments, each of the dielectric structures 240A, 240B, and 240C has a vertical sidewall. In these cases, an angle θ formed between the sidewall and the bottom of the dielectric structures 240A-240C is substantially equal to 90 degrees. However, embodiments of the disclosure are not limited thereto. In some other embodiments, one or more of the dielectric structures 240A-240C are formed to have inclined sidewalls, so as to fine-tune the capacitance according to requirements. The angle θ may be within a range from about 60 degrees to about 90 degrees.

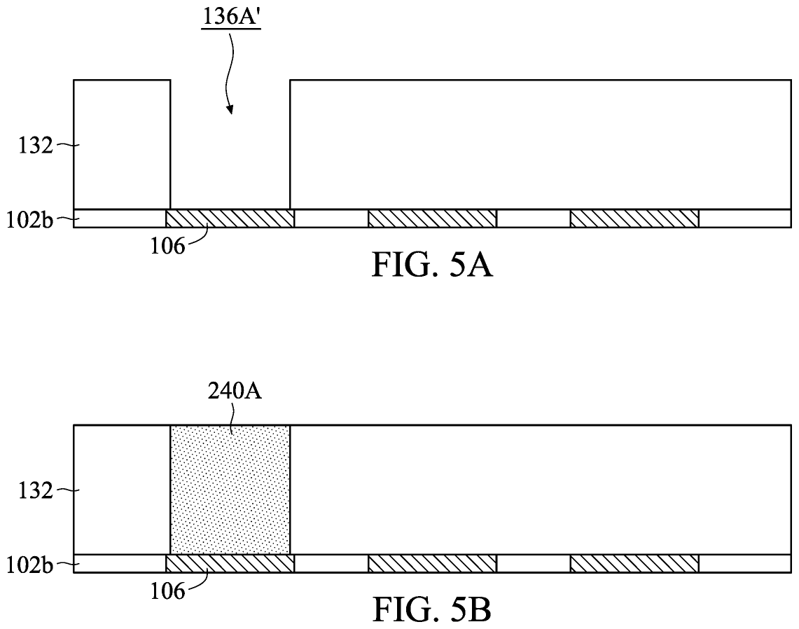

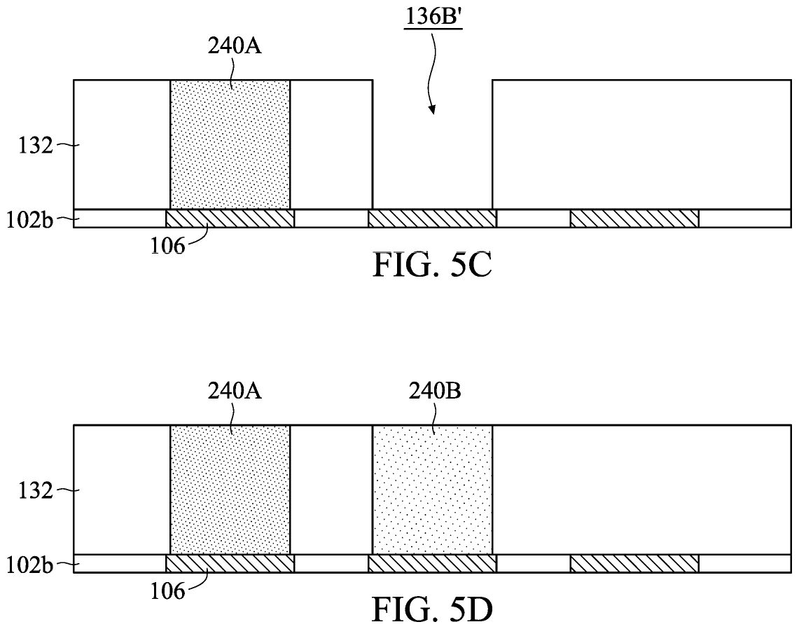

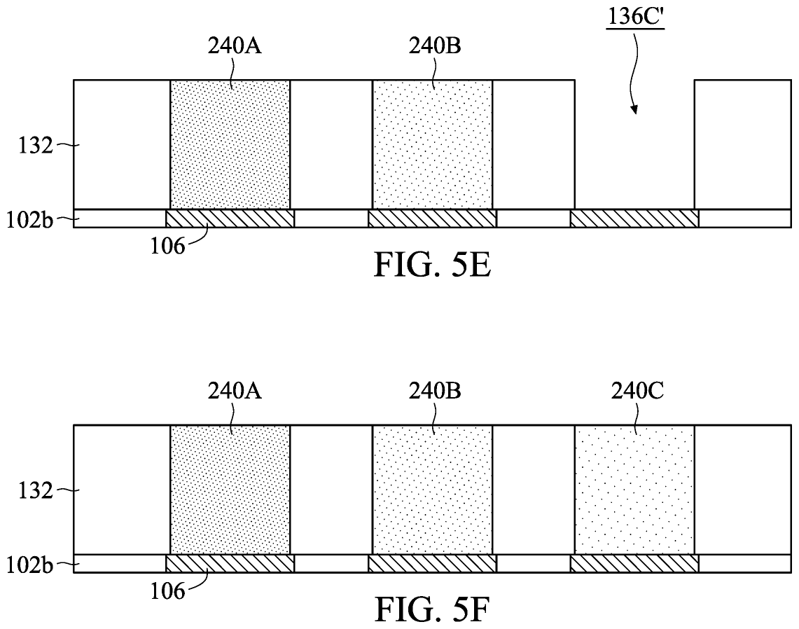

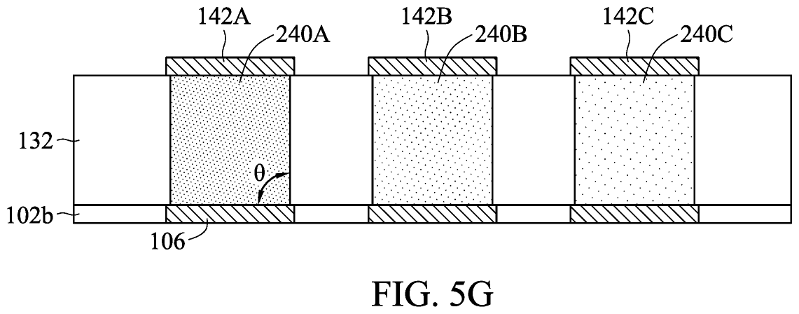

Many variations and/or modifications can be made to embodiments of the disclosure. FIGS. 5A-5G are cross-sectional views of various stages of a process for forming a portion of a package structure, in accordance with some embodiments. In some embodiments, FIGS. 5A-5G show the formation of the dielectric structures 240A-240C shown in FIG. 3.

As shown in FIG. 5A, the protective layer 132 is patterned to form an opening 136A′, in accordance with some embodiments. Afterwards, the dielectric structure 240A is formed in the opening 136A′, as shown in FIG. 5B in accordance with some embodiments.

As shown in FIG. 5C, the protective layer 132 is patterned to form an opening 136B′, in accordance with some embodiments. Afterwards, the dielectric structure 240B is formed in the opening 136B′, as shown in FIG. 5D in accordance with some embodiments. In some embodiments, the dielectric structures 240B and 240A are made of different materials. In some embodiments, the dielectric structure 240B has a lower dielectric constant than that of the dielectric structure 240A.

As shown in FIG. 5E, the protective layer 132 is patterned to form an opening 136C′, in accordance with some embodiments. Afterwards, the dielectric structure 240C is formed in the opening 136C′, as shown in FIG. 5F in accordance with some embodiments. In some embodiments, the dielectric structures 240C and 240B are made of different materials. In some embodiments, the dielectric structure 240C has a lower dielectric constant than that of the dielectric structure 240B.

As shown in FIG. 5G, similar to the embodiments illustrated in FIG. 1P, conductive features 142A, 142B, and 142C are respectively formed over the dielectric structures 240A, 240B, and 240C, in accordance with some embodiments. As a result, multiple capacitor elements are formed. In some embodiments, the capacitor element having the dielectric structure 240A has higher capacitance than that of the capacitor element having the dielectric structure 240B or 240C.

In some embodiments, each of the dielectric structures 240A, 240B, and 240C has a vertical sidewall. In these cases, an angle θ formed between the sidewall and the bottom of the dielectric structures 240A-240C is substantially equal to 90 degrees. However, embodiments of the disclosure are not limited thereto. In some other embodiments, one or more of the dielectric structures 240A-240C are formed to have inclined sidewalls, so as to fine-tune the capacitance according to requirements. The angle θ may be within a range from about 60 degrees to about 90 degrees.

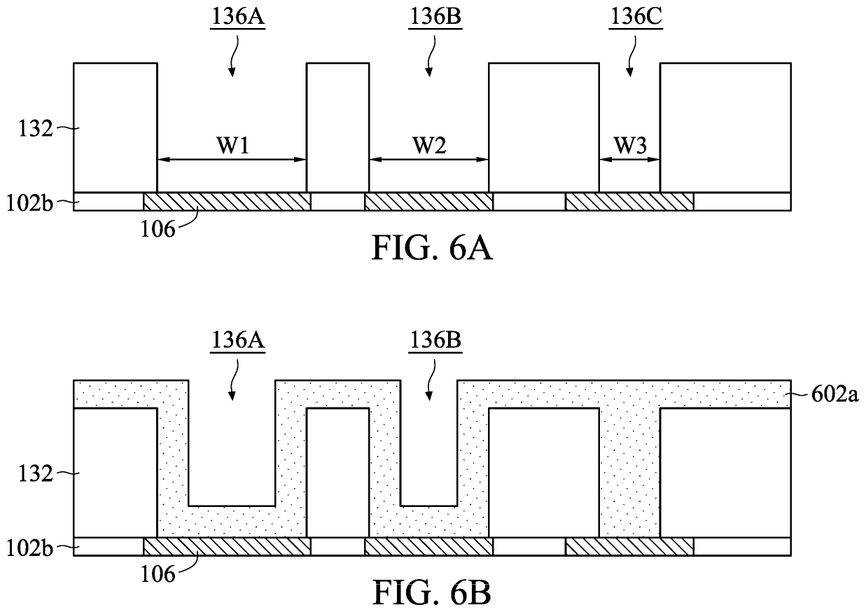

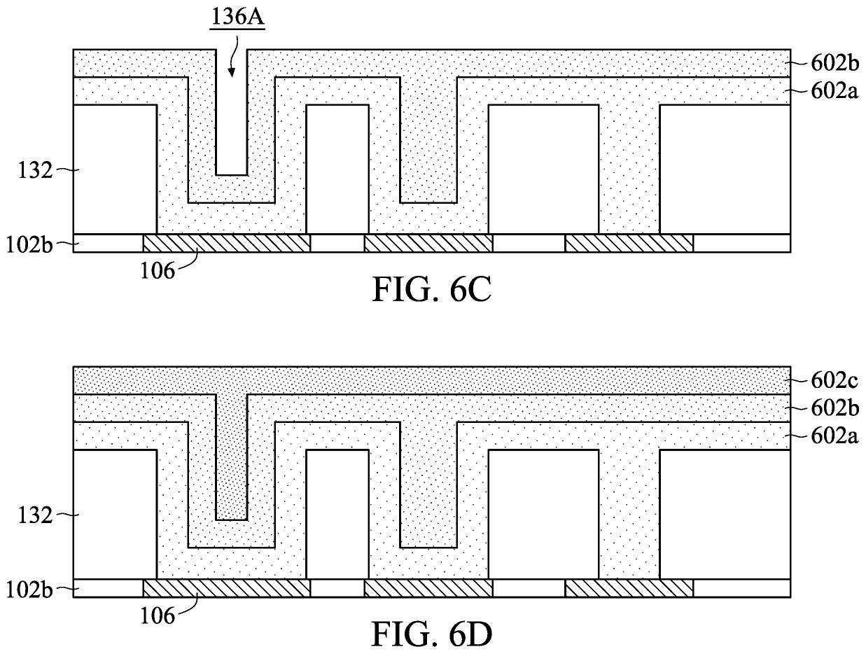

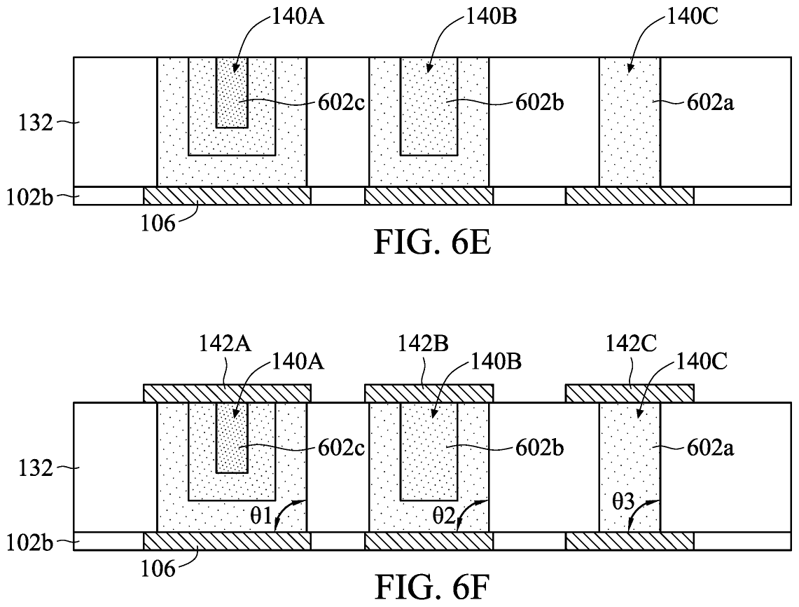

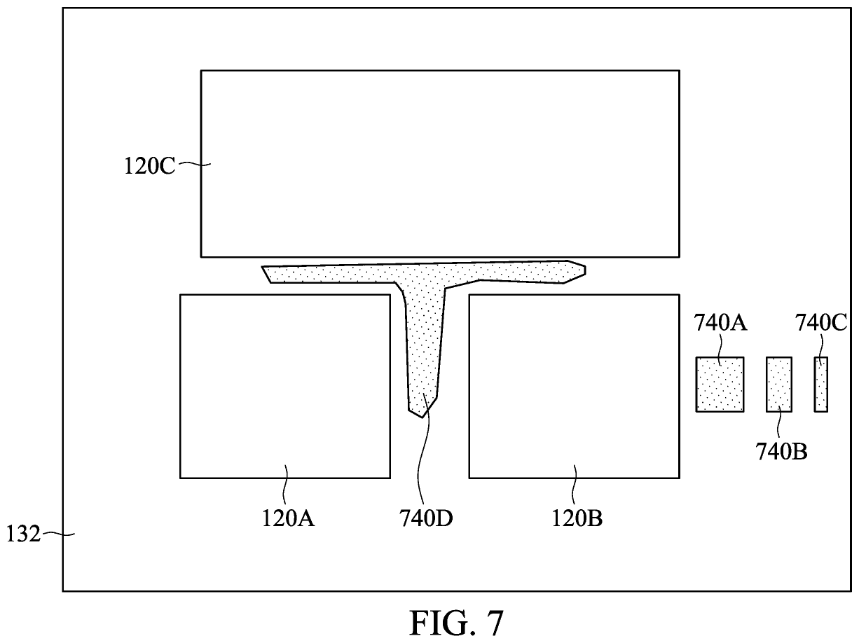

Many variations and/or modifications can be made to embodiments of the disclosure. In some embodiments, the dielectric structure includes two or more insulating layers. FIGS. 6A-6F are cross-sectional views of various stages of a process for forming a portion of a package structure, in accordance with some embodiments.

As shown in FIG. 6A, similar to the embodiments illustrated in FIGS. 1L-1M, the protective layer 132 is patterned to form openings 136A, 136B, and 136C, in accordance with some embodiments. In some embodiments, the opening 136A is wider than the opening 136B, and the opening 136B is wider than the opening 136C.

As shown in FIG. 6B, an insulating layer 602a is formed over the structure shown in FIG. 6A, in accordance with some embodiments. In some embodiments, the insulating layer 602a overfills the opening 136C that has the width W3. In some embodiments, the insulating layer 602a partially fills the openings 136A and 136B. The insulating layer 602a extends along the sidewalls and bottoms of the openings 136A and 136B. The material and formation method of the insulating layer 602a may be the same as or similar to those of the insulating layer 138 shown in FIG. 1N.

As shown in FIG. 6C, an insulating layer 602b is formed over the insulating layer 602a, in accordance with some embodiments. In some embodiments, the insulating layer 602b overfills the opening 136B. In some embodiments, the insulating layer 602b partially fills the opening 136A. Due to the occupation of the insulating layer 602a, the insulating layer 602b is prevented from entering the opening 136C.

The material and formation method of the insulating layer 602b may be the same as or similar to those of the insulating layer 138 shown in FIG. 1N. In some embodiments, the insulating layers 602a and 602b are made of different materials. In some embodiments, the insulating layers 602a and 602b have different dielectric constants. In some embodiments, the insulating layer 602b has a higher dielectric constant than that of the insulating layer 602a.

As shown in FIG. 6D, an insulating layer 602c is formed over the insulating layer 602b, in accordance with some embodiments. In some embodiments, the insulating layer 602c overfills the opening 136A. Due to the occupation of the insulating layer 602a, the insulating layer 602c is prevented from entering the opening 136C. Due to the occupation of the insulating layers 602a and 602b, the insulating layer 602c is prevented from entering the opening 136B.

The material and formation method of the insulating layer 602c may be the same as or similar to those of the insulating layer 138 shown in FIG. 1N. In some embodiments, two or more of the insulating layers 602a-602c are made of different materials. In some embodiments, two or more of the insulating layers 602a-602c have different dielectric constants. In some embodiments, the insulating layer 602c has a higher dielectric constant than that of the insulating layer 602b.

As shown in FIG. 6E, similar to the embodiments illustrated in FIGS. 1N-1O, the insulating layers 602a-602c are planarized, in accordance with some embodiments. A first remaining portion of the insulating layer 602a, a first remaining portion of the second insulating layer 602b, and the remaining portion of the insulating layer 602c together form a dielectric structure 140A. A second remaining portion of the insulating layer 602a and a second remaining portion of the insulating layer 602b together form a dielectric structure 140B. A third remaining portion of the insulating layer 602a forms a dielectric structure 140C.

As shown in FIG. 6F, similar to the embodiments illustrated in FIG. 1P, conductive features 142A, 142B, and 142C are respectively formed over the dielectric structures 140A, 140B, and 140C, in accordance with some embodiments. As a result, multiple capacitor elements are formed. In some embodiments, the capacitor element having the dielectric structure 140A has higher capacitance than that of the capacitor element having the dielectric structure 140B or 140C.

In some embodiments, each of the dielectric structures 140A, 140B, and 140C has a vertical sidewall. In these cases, sidewall angles θ1, θ2, and θ3 of the dielectric structures 140A-140C are substantially equal to 90 degrees. However, embodiments of the disclosure are not limited thereto. In some other embodiments, one or more of the dielectric structures 140A-140C are formed to have inclined sidewalls, so as to fine-tune the capacitance according to requirements. Each of the sidewall angles θ1, θ2, and θ3 may be within a range from about 60 degrees to about 90 degrees. In some embodiments, two or more of the sidewall angles θ1, θ2, and θ3 are the same. In some embodiments, two or more of the sidewall angles θ1, θ2, and θ3 are different.

Many variations and/or modifications can be made to embodiments of the disclosure. FIG. 7 is a plan view of a portion of a package structure, in accordance with some embodiments. In some embodiments, multiple semiconductor chips 120A, 120B, and 120C are laterally surrounded by the protective layer 132. In some embodiments, multiple dielectric structures 740A, 740B, 740C, and 740D of multiple capacitor elements are also laterally surrounded by the protective layer 132.

As mentioned in the embodiments illustrated in FIGS. 2A-2L, each of the dielectric structures 740A-740D may have varied sizes, profiles, and/or distribution. In some embodiments, the dielectric structures 740A-740C are positioned at the right side of the semiconductor chip 120B. In some embodiments, the dielectric structure 740D extends between the semiconductor chips 120A-120C.

Embodiments of the disclosure form a package structure with a protective layer (such as a molding layer) laterally surrounding one or more semiconductor chips and the dielectric structures of one or more embedded capacitor elements. The shapes, profiles, sizes, and materials of the dielectric structures may be varied so as to provide varied capacitance of the embedded capacitor elements. The capacitance and area of the capacitor elements are tunable, which greatly improve the routing flexibility. The embedded capacitor elements in the protective layer may provide capacitance that is within a range from about 100 fF to about 500 nF. The embedded capacitor elements have shorter interconnection length to the semiconductor chip, which allows a shorter time delay. The performance and reliability of the package structure are significantly improved, which is suitable for future advanced portable products such as new generation smart phones, flat panels, internet of things, cloud computing devices, and the like.

In accordance with some embodiments, a method for forming a package structure is provided. The method includes surrounding a semiconductor chip with a protective layer. The protective layer has a first dielectric constant. The method also includes partially removing the protective layer to form an opening. The method further includes forming a dielectric structure partially or completely filling the opening. The dielectric structure has a second dielectric constant, and the second dielectric constant is higher than the first dielectric constant. The method further includes forming a redistribution structure over the semiconductor chip, the protective layer, and the dielectric structure.

In accordance with some embodiments, a package structure is provided. The package structure includes a semiconductor chip and a dielectric structure laterally spaced apart from the semiconductor chip. The dielectric structure has a first dielectric constant. The package structure also includes a protective layer surrounding the semiconductor chip and the dielectric structure. The protective layer has a second dielectric constant, and the second dielectric constant is lower than the first dielectric constant. The package structure further includes a redistribution structure over the semiconductor chip, the dielectric structure, and the protective layer.

In accordance with some embodiments, a package structure is provided. The package structure includes a semiconductor chip and a capacitor element laterally spaced apart from the semiconductor chip. The capacitor has a first conductive feature, a dielectric structure, and a second conductive feature. The dielectric structure is between the first conductive feature and the second conductive feature. The package structure also includes a protective layer surrounding the semiconductor chip and the dielectric structure of the capacitor element. The package structure further includes a redistribution structure over the semiconductor chip, the capacitor element, and the protective layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a semiconductor chip;
a first dielectric structure laterally spaced apart from the semiconductor chip, wherein the first dielectric structure has a first dielectric constant;
a second dielectric structure laterally spaced apart from the semiconductor chip;
a protective layer laterally surrounding the semiconductor chip, the first dielectric structure, and the second dielectric structure, wherein the protective layer has a second dielectric constant, and the second dielectric constant is lower than the first dielectric constant; and
a redistribution structure over the semiconductor chip, the first dielectric structure, the second dielectric structure, and the protective layer.

2. The package structure as claimed in claim 1, wherein the first dielectric structure is substantially as thick as the protective layer.

3. The package structure as claimed in claim 1, wherein a first portion of the first dielectric structure and a second portion of the second dielectric structure are made of same material.

4. The package structure as claimed in claim 3, wherein a third portion of the first dielectric structure and the second portion of the second dielectric structure are made of different materials.

5. The package structure as claimed in claim 4, further comprising:
a third dielectric structure laterally surrounded by the protective layer.

6. The package structure as claimed in claim 5, wherein a fourth portion of the third dielectric structure and the first portion of the first dielectric structure have a same dielectric constant.

7. The package structure as claimed in claim 5, wherein a fourth portion of the third dielectric structure and the third portion of the first dielectric structure have different dielectric constants.

8. The package structure as claimed in claim 5, wherein at least two of the first dielectric structure, the second dielectric structure, and the third dielectric structure have different widths.

9. The package structure as claimed in claim 1, further comprising:
a first conductive feature;
a second conductive feature, wherein the first dielectric structure is between the first conductive feature and the second conductive feature; and
a first conductive bump and a second conductive bump disposed over a same side of the redistribution structure, wherein the first conductive bump is electrically connected to the first conductive feature, and the second conductive bump is electrically connected to the second conductive feature.

10. The package structure as claimed in claim 1, wherein the first dielectric structure is substantially as tall as the second dielectric structure.

11. A package structure, comprising:
a semiconductor chip;
a first capacitor element laterally spaced apart from the semiconductor chip, wherein the first capacitor has a first conductive feature, a first dielectric structure, and a second conductive feature, and the first dielectric structure is between the first conductive feature and the second conductive feature;
a second capacitor element laterally spaced apart from the semiconductor chip, wherein the second capacitor has a third conductive feature, a second dielectric structure, and a fourth conductive feature, and the second dielectric structure is between the third conductive feature and the fourth conductive feature;
a protective layer surrounding the semiconductor chip, the first dielectric structure of the first capacitor element, and the second dielectric structure of the second capacitor element; and
a redistribution structure spans the semiconductor chip, the first capacitor element, and the second capacitor element.

12. The package structure as claimed in claim 11, further comprising:
a grounding bump formed on the redistribution structure, wherein the grounding bump is electrically connected to the second conductive feature of the first capacitor element and the fourth conductive feature of the second capacitor element.

13. The package structure as claimed in claim 12, further comprising:
a conductive bump formed on the redistribution structure, wherein the conductive bump is electrically connected to the second conductive feature of the first capacitor element.

14. The package structure as claimed in claim 11, wherein a first portion of the first dielectric structure and a second portion of the second dielectric constant are made of a same material.

15. The package structure as claimed in claim 11, wherein the first dielectric structure has a first dielectric layer and a second dielectric layer, the first dielectric layer and a portion of the second dielectric structure are made of different materials.

16. A package structure, comprising:
a semiconductor chip;
a first capacitor element laterally spaced apart from the semiconductor chip, wherein the first capacitor has a first dielectric structure;
a second capacitor element laterally spaced apart from the semiconductor chip, wherein the second capacitor has a second dielectric structure, and the first dielectric structure is wider than the second dielectric structure;
a protective layer surrounding the semiconductor chip, the first dielectric structure, and the second dielectric structure; and
a redistribution structure spans the semiconductor chip, the first capacitor element, and the second capacitor element.

17. The package structure as claimed in claim 16, wherein a first portion of the first dielectric structure and a second portion of the second dielectric structure are made of a same material.

18. The package structure as claimed in claim 17, wherein a third portion of the first dielectric structure and the second portion of the second dielectric structure are made of different materials.

19. The package structure as claimed in claim 16, further comprising:
a first conductive bump electrically connected to a conductive feature of the semiconductor chip;
a first electrode and a second electrode, wherein the first dielectric structure is between the first electrode and the second electrode;
a second conductive bump electrically connected to the first electrode; and
a third conductive bump electrically connected to the second electrode.

20. The package structure as claimed in claim 19, wherein the first conductive bump, the second conductive bump, and the third conductive bump are located on a same side of the redistribution structure.
